(19) United States
(12) Patent Application Publication
(10) Pub. No.: US 2015/0179469 A1
(43) Pub. Date: Jun. 25, 2015

(54) METHOD AND SYSTEM TO CONTROL POLISH RATE VARIATION INTRODUCED BY DEVICE DENSITY DIFFERENCES

(71) Applicants: Sridhar Govindaraju, Hillsboro, OR (US); Matthew J. Prince, Portland, OR (US); Rohit Grover, West Linn, OR (US)

(72) Inventors: Sridhar Govindaraju, Hillsboro, OR (US); Matthew J. Prince, Portland, OR (US); Rohit Grover, West Linn, OR (US)

(21) Appl. No.: 14/137,512

(22) Filed: Dec. 20, 2013

(51) Int. Cl. H01L 21/3105; H01L 21/311

(52) U.S. Cl. CPC H01L 21/31053; H01L 21/31111

(57) ABSTRACT

An embodiment includes forming a first film over first and second portions of a SOC, the first portion including a first density of structures and the second portion including a second density of structures with the first density being denser than the second density; forming a second film over the first film; polishing the second film to remove some of the second film and form (a) a first section of the second film between sections of the first film located over the first portion, and (b) a second section of the second film between sections of the second film located over the second portion; etching the first film over the first and second portions and etching the first and second sections of the second film; and polishing the first film to expose top surfaces of the structures of the first and second portions. Other embodiments are described herein.

### TECHNICAL FIELD

Embodiments of the invention are in the field of semiconductor devices and, in particular, wafer processing.

### BACKGROUND

Once semiconductor wafers are prepared, a large number of process steps are still necessary to produce desired semiconductor integrated circuits. In general the steps can be grouped into four areas: Front End Processing, Back End Processing, Test, and Packaging.

Front End Processing refers to the initial steps in the fabrication. In this stage the actual semiconductor devices (e.g., transistors) are created. A typical front end process includes: preparation of the wafer surface, patterning and subsequent implantation of dopants to obtain desired electrical properties, growth or deposition of a gate dielectric, and growth or deposition of insulating materials to isolate neighboring devices.

Once the semiconductor devices have been created they must be interconnected to form the desired electrical circuits. This “Back End Processing” involves depositing various layers of metal and insulating material in the desired pattern. Typically the metal layers consist of aluminum, copper, and the like. The insulating material may include SiO₂, low-K materials, and the like. The various metal layers are interconnected by interconnects, which may include a line portion and a via portion. Vias may be formed by etching holes in the insulating material and depositing metal (e.g., Tungsten, or copper, with appropriate adhesion films) in them. The line portion may be formed by etching trenches in the insulating material and depositing metal in them.

Once the Back End Processing has been completed, the semiconductor devices are subjected to a variety of electrical tests to determine if they function properly. Finally, the wafer is cut into individual die, which are then packaged in packages (e.g., ceramic or plastic packages) with pins or other connectors to other circuits, power sources, and the like.

### BRIEF DESCRIPTION OF THE DRAWINGS

Features and advantages of embodiments of the present invention will become apparent from the appended claims, the following detailed description of one or more example embodiments, and the corresponding figures, in which:

FIGS. 1A-1B are cross-sectional side view illustrations of a conventional method of polishing semiconductor devices.

FIGS. 2A-E are cross-sectional side view illustrations of a method of polishing semiconductor devices in an embodiment of the invention.

FIG. 3 is a flow chart illustrating a method of polishing semiconductor devices in an embodiment of the invention.

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

A modern microprocessor consists of numerous functional blocks, such as a core for computational logic, cache, and graphics controller. With continued industry momentum towards integration, a modern microprocessor may even comprise a complete system on a chip or system on chip (SOC). SOCs are integrated circuits (IC) that integrates components of a computer or other electronic system into a single chip. They may contain digital, analog, mixed-signal, and often radio-frequency functions—all on a single chip substrate. A typical application is in the area of embedded systems. A typical SOC may consist of (1) a microcontroller, microprocessor or digital signal processing (DSP) core(s), (2) memory blocks including a selection of ROM, RAM, EEPROM and flash memory, (3) timing sources including oscillators and phase-locked loops, (4) peripherals including counter-timers, real-time timers and power-on reset generators, (5) external interfaces including industry standards such as USB, FireWire, Ethernet, USART, SPI, (6) analog interfaces including ADCs and DACs, (7) voltage regulators and power management circuits, and the like. These blocks are connected by a proprietary or industry-standard bus.

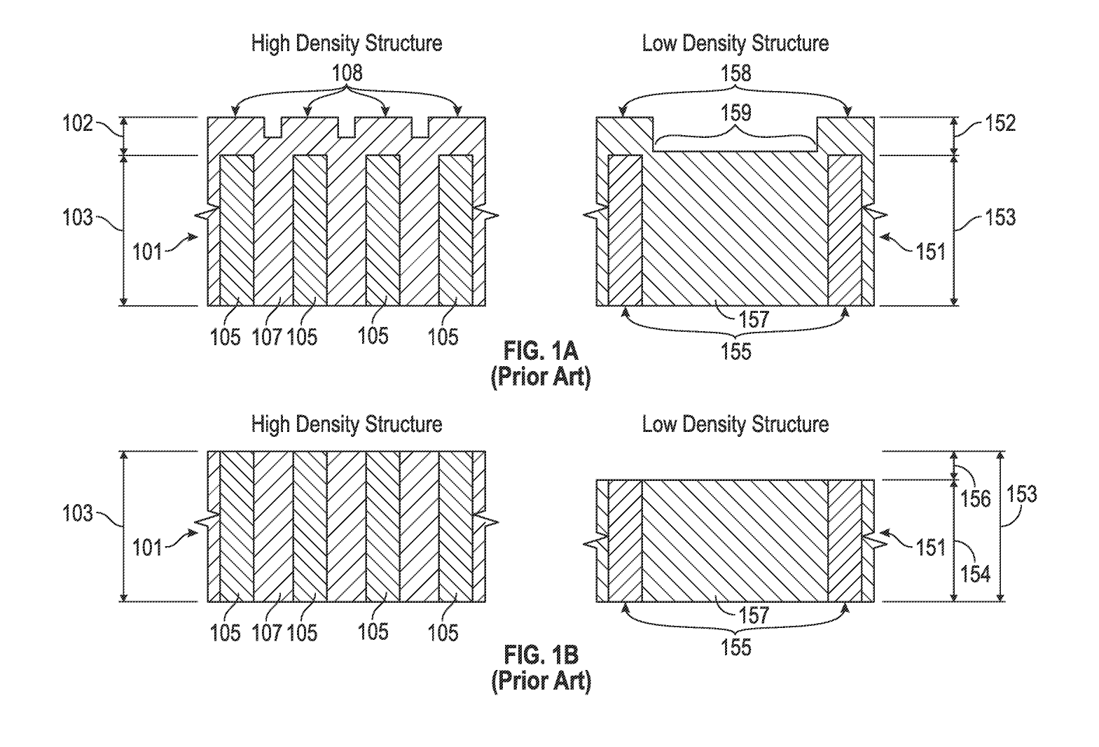

FIG. 1A includes two portions 101, 151 of a semiconductor device. These two portions may be portions taken from opposite ends of a wafer or die or may be reasonably proximate to each other. For illustrative purposes portion 101 may be considered to be a logic portion (e.g., controller) and portion 151 may be considered to be an analog portion (e.g., radio). For reasons of circuit functionality, the area density of various circuit elements such as interconnects, transistor contacts, transistor gate metal or poly (for transistor), resistors, and other in-plane circuit elements will not match between functional blocks. For example, logic portion 101 may be more “dense” than analog portion 151. Mismatches between structure density of functional blocks of the microprocessor become increasingly disparate with continued integration of newer functionality, as with systems on a chip. This density may be based on structures 105, 151 whereby there are more structures 105 per unit area than there are structures 151 per unit area. Structures 105, 151 may be any structure such as an interconnect, gate dielectric (e.g., polysilicon) for a transistor or switching device, etched out portions of the substrate, and the like. Structures may be formed within material 107, 157. Material 107, 157 may be a dielectric such as an oxide or nitride film used to isolate structures 105, 155. Structures 105, 155 and/or materials 107, 157 may be considered films deposited in any number of ways, such as by atomic layer deposition (ALD), chemical vapor deposition (CVD), physical vapor deposition (PVD), electroplating, electroless plating or other suitable process.

The issue for structures 105, 155 and portions 107, 157 is not so much the exact nature or purposes or material make-up of the structures 105, 155 and portions 107, 157 as the fact that there are portions of device that are different from one another (structures 105, 155 are different from materials 107, 157) and the presence of one within the other (structures 105, 155 within materials 107, 157) create a differential in structure density between different portions of a device (e.g., portion 101 has greater structural density than portion 151).

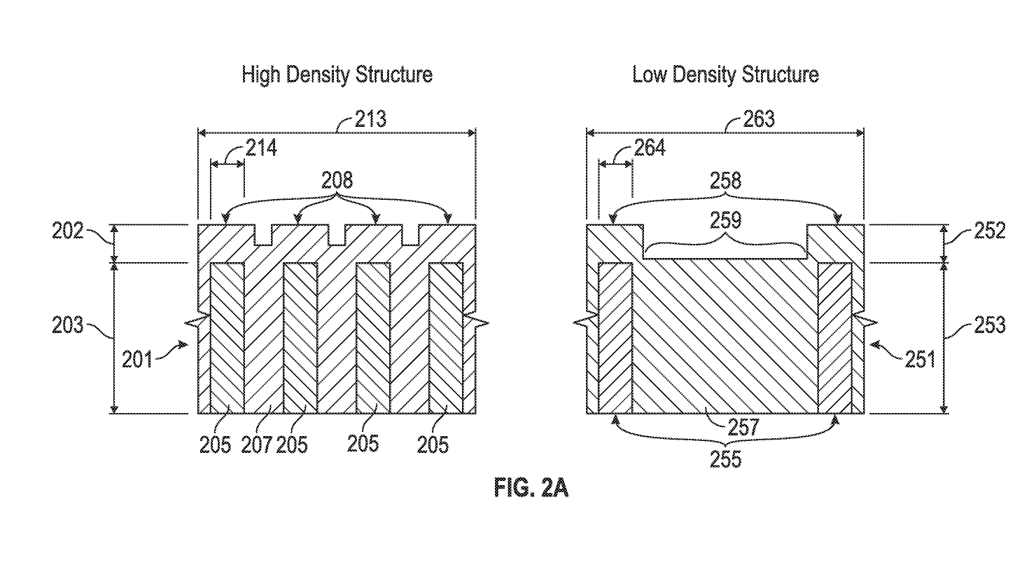

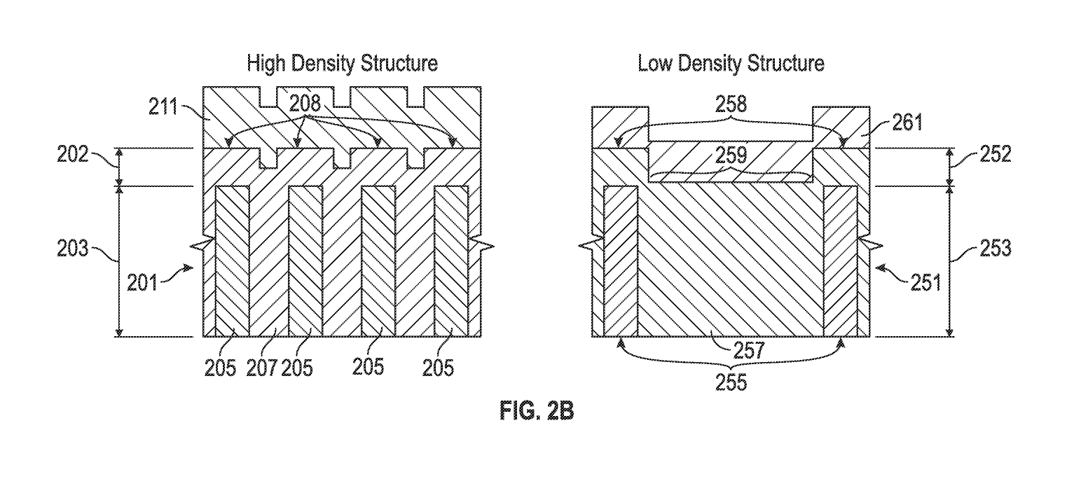

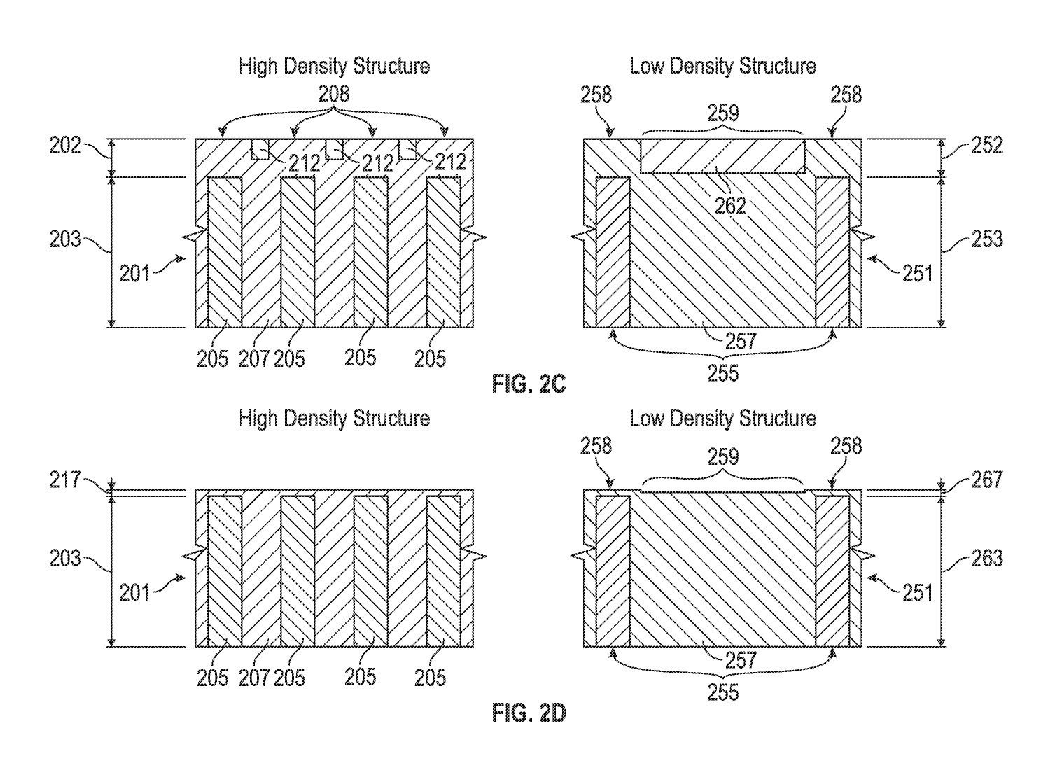

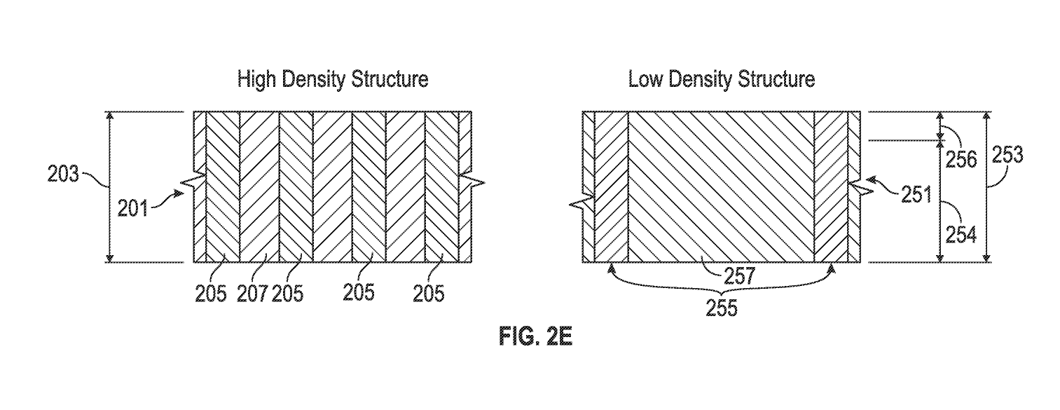

FIG. 2A thus depicts two portions 101, 151 of a device. The device may require polishing to removing the portions of materials 107, 157 that extend above structures 105, 155. This polishing may be due to typical processing and layer buildup in front end or back end processing. The desired polishing may target removal of all material 107, 157 located in range 102, 152. This polishing may include chemical mechanical polishing (CMP).

In an embodiment CMP uses an abrasive and corrosive chemical slurry (colloid) in conjunction with a polishing pad and retaining ring, typically of a greater diameter than the wafer. The pad and wafer are pressed together by a dynamic polishing head and held in place by a plastic retaining ring. The dynamic polishing head may be rotated with different axes of rotation. This removes material and tends to even out any irregular topography of the surface being polished, making the wafer flat or planar. This may be necessary in order to set up the wafer for the formation of additional circuit elements and to generally further backend or frontend processing. For example, this might be necessary in order to bring the entire surface within the depth of field of a photolithography system, or to selectively remove material based on its position. Typical depth-of-field requirements are down to Angstrom levels for 22 nm technology.

Polishing, such as CMP, has made great advancements over the years but is not without shortcomings. For example, polishing such as films 107, 157 with various underlying densities will result in polish rate variation introduced by those density differences. For example, films 107, 157 may each include an oxide but as mentioned above, films 107, 157 are in portions 101, 151 that have different densities due to structures 105, 155. As the single pad polishes both 101 and 151 the pad dips lower in the less dense portions, such as portion 159, than it does over portions 108, 158, which are located over structures 105, 155. As a result, this dipping of the pad exerts greater force on portion 158 than it does on portion 108. As the polish proceeds, this greater force applied to 158 becomes greater force applied to structures 155, located below portions 158. FIG. 2B shows the result. A pad used to polish portions 101, 151 to a desired target range 103, which extends just to the top of structures 105, undesirably reduces structures 155 to an undesired level 154, which is a differential 156 below the desired height 103, 153 for structures 105, 155. To avoid the “over polishing” of structures 155 one would have to stop the polish that is too far above structures 105.

Thus, density variation due to structures 105, 155 translates into different heights for the structures (structures 105 are taller than structures 155), primarily dominated by the micro and macro scale density variation. More specifically, some CMP equipment can apply different pressures to different portions of a pad. Thus, a lighter pressure can be applied to the pad over less dense areas and a stronger presser can be applied to the pad over denser areas. However, these tools can only apply this differential pressure on a macro scale that at best is applied to entire wafers (e.g., wafer having a diameter of 50 mm). However, this is more difficult on a micro level such as within a single SOC (e.g., within a 10 mm×10 mm space), such as applying a lighter pressure to area 151 than 101. This technique would result in high “within die” depth variation. In contrast, using hard pads may help “within die” depth variation as they are more rigid and less likely to differ in depth between relatively nearby structures in a SOC. However such hard pads may instead have larger differences in pressure across different portions of a wafer due to lack of compliance to compensate against pressure variations from the wafer chuck, and thus demonstrate high “within wafer” variation. Also, hard pads are more likely to scratch the wafer than soft pads. For example, a hard pad is less likely to conform over slurry particulate matter or debris that may cause a scratch in the wafer and make the wafer/die unsuitable for sale or use.

An embodiment provides both low within wafer polish height variation and low within die polish height variation. This is a significant advancement because no conventional techniques provide both within wafer and within die control for polishing various films on wafers, such as wafers including silicon nitride for materials 107 and/or 157.

FIGS. 2A-E are cross-sectional side view illustrations of a method of polishing semiconductor devices in an embodiment of the invention.

FIG. 2A includes two portions 201, 251 of a semiconductor device. These two portions may be portions taken from opposite ends of a wafer or die or may be reasonably proximate to each other. For illustrative purposes portion 201 may be considered to be a logic portion (e.g., controller) and portion 251 may be considered to be an analog portion (e.g., radio). FIG. 2A is analogous to FIG. 1A. Logic portion 201 may be more “dense” than analog portion 251 (which has relatively less dense portion 259). This density may be based on the area or volume of structures 205, 251 whereby there is more area or volume due to structures 205 per unit area than there is area or volume due to structures 251 per unit area. For example, as illustrated in FIG. 2A portion 201 has four structures each having width 214 in a portion having a width 213. Portion 251 has two structures each having width 264 (equal to width 214) in a portion having a width 263 (equal to width 213). Thus, if both portion 201 and 251 have equivalent depth (not shown in 2 dimensional rendering FIG. 2A, where depth goes into the page) then, for illustrative purposes, structures 205 compose about 48% of portion 201 and structures 251, compose about 24% of portion 251 such that portion 201 is about 2.0× the density of portion 251. However, other embodiments may not be so limited and portion 201 may be 1.25, 1.50, 1.75, 2.25× or more the density of portion 251. The figures herein are not to scale but are provided for illustrative purposes.

Structures 205, 251 may be any structure such as an interconnect, gate dielectric (e.g., polysilicon) for a transistor or switching device, etched out portions of the substrate, and the like. Structures may be formed within material 207, 257. Material 207, 257 may be a dielectric such as an oxide or nitride film used to isolate structures 205, 255. Structures 205, 255 and/or materials 207, 257 may be considered films deposited in any number of ways, such as by ALD, CVD, PVD, electroplating, electroless plating or other suitable process.

In FIG. 2B film 211, 261 (which are depicted separately but in fact may or may not be monolithic and deposited simultaneously) is deposited on films 207, 257. Film 211, 261 has a different property than film 207, 257 from the “polish pad/slurry” perspective. In other words, film 211, 261 has a different property than film 207, 257 in terms of chemical composition and its ability or rate of polish with the slurry and pad used in polishing. In an embodiment the pad/slurry combination used to polish film 211, 261 has a “chemical stopping potential” for 207, 257; such pad/slurry combinations are commonly referred to as “selective”. In other words, the pad/slurry chemical composition is such that is does not readily polish film 207, 257 but does readily polish film 211, 261. In an embodiment, film 207, 257 includes a nitride, which is a compound of nitrogen where nitrogen has a formal oxidation state of −3 (e.g., silicon nitride such as Si₃N₄). Film 211, 261 includes an oxide such as, for example, silicon dioxide SiO₂, SiOF, carbon-doped oxide, a glass or polymer material, and the like. A slurry of silica and water may be used when films 207, 257 include Si₃N₄ and films 211, 261 include SiO₂. In an embodiment, film 207, 257 includes an oxide, which is a chemical compound that contains at least one oxygen atom and one other element in its chemical formula. In an embodiment the structures 205, 257 may include copper, aluminum, cobalt, tungsten, polysilicon, silicon, germanium, and the like. Again, the combinations of materials to be used for structures 205, 255; film 207, 257; film 211, 261; and slurry/pad are many and the chemical interplay between them is known to those of ordinary skill in the art.

In FIG. 2C the film 211, 261 is polished down to the tops of structures 208, 258. This is done using a chemically selective slurry that does not polish film 207, 257. For example, for film 207, 257 including silicon nitride, a slurry including ceria particles in water, with surfactants configured to promote surface wetting and subsequent removal of slurry residues from the wafer surface may be used. This results in a planar surface post film 211, 261 polish. The planar property is based on a topography that has film 211, 261 portions 212, 262 having a top surface equal in height/level to the top of film 207, 257.

In FIG. 2D an etch chemistry, which is tuned for selectivity for film 207, 257 and film 211, 261, is used to etch those two films with a “blanket” rate (i.e., substantially equal rate) leaving a relatively planar surface with “minor” topography after etch. The etch may be timed or monitored to ensure the etch stops when the minor topography is achieved. By “minor topography” what is meant is that the top surface of portions 201, 251 is not completely smooth due to the small range 217, 267 of material 207, 257 over structures 205, 255. In another embodiment, the minor topography may be based on other factors such as an etch that slightly etches the material 207, 257 faster than material 211, 261 resulting in upper islands of material 207, 257 that higher between the structures 205, 255 rather than over them (as is the case in FIG. 2D).

At this point metrology, such as optical interference based metrology, is used to detect an endpoint such as the top of structures 205, 255. This detection would indicate a height 203, 263 (which are equal to one another) that could then be subtracted from the detected edge at the top of 207, 257 to determine a differential 217, 267.

In FIG. 2E differential 217, 267 could be used in a targeted polish process (targeted to polish only the depth 217, 267 using structures 205, 255 a stopping layer) to clean the minor topography left after the etch of FIG. 2C (which was used to obtain FIG. 2D) and target the intended height post polish (i.e., height 203, 253). Note how height 253 is differential 256 beyond the final height 254 of portion 251 in FIG. 1B.

Thus, embodiments include a method that includes an etch step instead of the all polish technique described for FIGS. 1A and B. Using one or more etch steps (e.g., FIG. 2D) helps avoid or lessen a polish, like polishing Si₃N₄ in 207, 257, which can induce an undesirable charge. As can be seen, the majority of the 207, 257 removal is by etch and not by polish (see FIGS. 2C and 2D). Only a small amount of polishing (see range 217, 267) is needed in some embodiments.

Also, an embodiment provides uniform depth of polishing, which produces better product yield. For example, when there is poor polish depth control a less dense SOC portion (e.g., analog radio portions) may be polished out in the process of polishing more dense logic areas of the SOC. Furthermore, uneven polishing may provide a floor for a metal layer (e.g., M0, M1, M2 . . . M10) that is uneven. This may lead to interconnects (lines formed in a metal layer) that have greater depth in some areas than others, leading to lower resistance in the deeper areas than in the thinner areas. The inconsistent resistances can lead to impedance matching issues and current bottle necks. Also, a metal deposited to deeply may not be fully removed in a subsequent processing stop. The inadvertently remaining metal portion may then cause a short or otherwise cause device failure. The controlled polish depth of embodiments addressed herein helps address at least these issues.

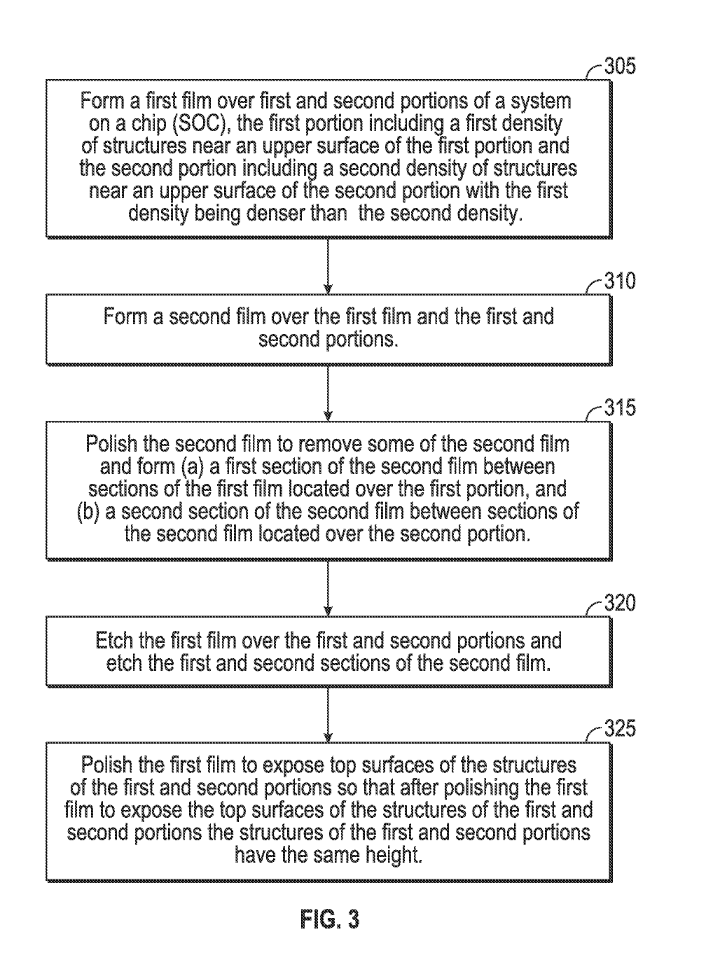

FIG. 3 includes a method 300 in an embodiment. Block 305 includes forming a first film over first and second portions of a system on a chip (SOC), the first portion including a first density of structures near an upper surface of the first portion and the second portion including a second density of structures near an upper surface of the second portion with the first density being denser than the second density. Block 310 includes forming a second film over the first film and the first and second portions. Block 315 includes polishing the second film to remove some of the second film and form (a) a first section of the second film between sections of the first film located over the first portion, and (b) a second section of the second film between sections of the second film located over the second portion. Block 320 includes etching the first film over the first and second portions and etching the first and second sections of the second film. Block 325 includes polishing the first film to expose top surfaces of the structures of the first and second portions so that after polishing the first film to expose the top surfaces of the structures of the first and second portions the structures of the first and second portions have the same height.

Although embodiments may be ideally suited for fabricating semiconductor ICs such as, but not limited to, microprocessors, memories, charge-coupled devices (CCDs), system on chip (SoC) ICs, or baseband processors, other applications can also include microelectronic machines, MEMS, lasers, optical devices, packaging layers, and the like. Embodiments may also be used to fabricate individual semiconductor devices (e.g., an interconnect structure described herein may be used to fabricate a gate electrode of a MOS transistor). Various embodiments may be included in, for example, a mobile computing node such as a cellular phone, Smartphone, tablet, Ultrabook®, notebook, laptop, personal digital assistant, and mobile processor based platform.

Various embodiments include a semiconductive substrate. Such a substrate may be a bulk semiconductive material this is part of a wafer. The substrate may form a portion of structures (e.g., structures 205 and/or 255). In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The following examples pertain to further embodiments.

Example 1 includes a method comprising: forming a first film over first and second portions of a system on a chip (SOC), the first portion including a first density of structures near an upper surface of the first portion and the second portion including a second density of structures near an upper surface of the second portion with the first density being denser than the second density; forming a second film over the first film and the first and second portions; polishing the second film to remove some of the second film and form (a) a first section of the second film between sections of the first film located over the first portion, and (b) a second section of the second film between sections of the second film located over the second portion; etching the first film over the first and second portions and etching the first and second sections of the second film; and polishing the first film to expose top surfaces of the structures of the first and second portions.

Another version of example 1 includes a method comprising: forming a first film over first and second portions of a system on a chip (SOC), the first portion including a first density of structures and the second portion including a second density of structures with the first density being denser than the second density; forming a second film over the first film and the first and second portions; polishing the second film to remove some of the second film and form (a) a first section of the second film between sections of the first film located over the first portion, and (b) a second section of the second film between sections of the second film located over the second portion; etching the first film over the first and second portions and etching the first and second sections of the second film; and polishing the first film to expose top surfaces of the structures of the first and second portions.

In example 2 the subject matter of the Example 1 can optionally include comprising simultaneously polishing the second film to form the first and second sections.

In example 3 the subject matter of the Examples 1-2 can optionally include simultaneously etching the first film and the first and second sections.

In example 4 the subject matter of the Examples 1-3 can optionally include simultaneously etching the first and second sections at an equal etch rate.

In example 5 the subject matter of the Examples 1-4 can optionally include polishing the first film with a soft pad and the second film with at least one of the soft pad and an additional soft pad. The term “soft pad” is a relative term that depends on specific applications and is understood to those having ordinary skill in the art.

In example 6 the subject matter of the Examples 1-5 can optionally include wherein polishing the second film comprises exerting a first pressure on a pad over the first portion and a second pressure on the pad over the second portion, the first and second pressures being substantially equal.

In example 7 the subject matter of the Examples 1-6 can optionally include wherein after polishing the first film to expose the top surfaces of the structures of the first and second portions the structures of the first and second portions have the same height.

In example 8 the subject matter of the Examples 1-7 can optionally include wherein (a) the structures include at least one of copper, aluminum, polysilicon, and a substrate upon which the SOC is formed, (b) the first film includes a nitride, and (c) the second film includes an oxide.

In example 9 the subject matter of the Examples 1-8 can optionally include wherein the first film includes silicon nitride.

In example 10 the subject matter of the Examples 1-9 can optionally include wherein forming the first film includes depositing the first film using at least one of atomic layer deposition (ALD), chemical vapor deposition (CVD), physical vapor deposition (PVD), electroplating, and electroless plating.

In example 11 the subject matter of the Examples 1-10 can optionally include wherein the first portion includes a logic portion and the second portion include an analog portion.

In example 12 the subject matter of the Examples 1-11 can optionally include forming the first film over an additional first portion of an additional SOC that is included in a wafer that also includes the SOC, the additional first portion including additional structures near an upper surface of the additional first portion; etching the first film over the additional first portion; and polishing the first film to expose top surfaces of the additional structures; wherein after polishing the first film to expose the top surfaces of the structures and the additional structures the structures and the additional structures have the same height.

In example 13 the subject matter of the Examples 1-12 can optionally include wherein polishing the second film includes using polish the second film with a slurry chemically configured to avoid polishing the first film.

In example 14 the subject matter of the Examples 1-13 can optionally include wherein the slurry includes ceria particles in water, with surfactants configured to promote surface wetting and subsequent removal of slurry residues from the wafer surface.

In example 15 the subject matter of the Examples 1-14 can optionally include wherein the sections of the first film comprises posts that are elevated over other top surfaces of the first film.

In example 16 the subject matter of the Examples 1-15 can optionally include wherein polishing the first film to expose the top surfaces of the structures includes polish no more than 20 nanometers of the first film. However, in other embodiments polishing may not need to exceed 5, 7, 10, 13, or 15 nanometers.

Example 17 includes a method comprising: forming a first film over first and second portions of a SOC, the first portion including a first density of first structures and the second portion including a second density of second structures that is less dense than the first density; forming a second film over the first film; polishing the second film to remove some but not all of the second film; simultaneously etching the first and second film; and polishing the first film to expose top surfaces of the first and second structures.

In example 18 the subject matter of the Example 17 can optionally include wherein simultaneously etching the first and second films includes etching the first and second films at an approximately equal etch rate.

In example 19 the subject matter of the Examples 17-18 can optionally include wherein polishing the second film comprises exerting a first pressure on a pad over the first portion and a second pressure on the pad over the second portion, the first and second pressures being substantially equal.

In example 20 the subject matter of the Examples 17-19 can optionally include wherein after polishing the first film to expose the top surfaces the first and second structures have the same height.

In example 21 the subject matter of the Examples 17-20 can optionally include wherein (a) the first and second structures include at least one of copper, aluminum, polysilicon, and a substrate upon which the SOC is formed, (b) the first film includes a nitride, and (c) the second film includes an oxide.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method comprising:
forming a first film over first and second portions of a system on a chip (SOC), the first portion including a first density of structures and the second portion including a second density of structures with the first density being denser than the second density;
forming a second film over the first film and the first and second portions;
polishing the second film to remove some of the second film and form (a) a first section of the second film between sections of the first film located over the first portion, and (b) a second section of the second film between sections of the second film located over the second portion;
etching the first film over the first and second portions and etching the first and second sections of the second film; and
polishing the first film to expose top surfaces of the structures of the first and second portions.

2. The method of claim 1 comprising simultaneously etching the first film and the first and second sections.

3. The method of claim 2 comprising simultaneously etching the first and second sections at an equal etch rate.

4. The method of claim 1 comprising polishing the first film with a soft pad and the second film with at least one of the soft pad and an additional soft pad.

5. The method of claim 1, wherein polishing the second film comprises exerting a first pressure on a pad over the first portion and a second pressure on the pad over the second portion, the first and second pressures being substantially equal.

6. The method of claim 1, wherein after polishing the first film to expose the top surfaces of the structures of the first and second portions the structures of the first and second portions have the same height.

7. The method of claim 1, wherein (a) the structures include at least one of copper, aluminum, polysilicon, and a substrate upon which the SOC is formed, (b) the first film includes a nitride, and (c) the second film includes an oxide.

8. The method of claim 7, wherein the first film includes silicon nitride.

9. The method of claim 1, wherein forming the first film includes depositing the first film using at least one of atomic layer deposition (ALD), chemical vapor deposition (CVD), physical vapor deposition (PVD), electroplating, and electroless plating.

10. The method of claim 1, wherein the first portion includes a logic portion and the second portion include an analog portion.

11. The method of claim 1 comprising:
forming the first film over an additional first portion of an additional SOC that is included in a wafer that also includes the SOC, the additional first portion including additional structures;
etching the first film over the additional first portion; and
polishing the first film to expose top surfaces of the additional structures;
wherein after polishing the first film to expose the top surfaces of the structures and the additional structures the structures and the additional structures have the same height.

12. The method of claim 1 wherein polishing the second film includes polishing the second film with a slurry chemically configured to avoid polishing the first film.

13. The method of claim 12, wherein the slurry includes ceria particles in water with surfactants configured to promote surface wetting and subsequent removal of slurry residues from the wafer surface.

14. The method of claim 1, wherein the sections of the first film comprises posts that are elevated over other top surfaces of the first film.

15. The method of claim 1, wherein polishing the first film to expose the top surfaces of the structures includes polishing no more than 20 nanometers of the first film.

16. A method comprising:
forming a first film over first and second portions of a SOC, the first portion including a first density of first structures and the second portion including a second density of second structures that is less dense than the first density;
forming a second film over the first film;
polishing the second film to remove some but not all of the second film;
simultaneously etching the first and second films; and
polishing the first film to expose top surfaces of the first and second structures.

17. The method of claim 16, wherein simultaneously etching the first and second films includes etching the first and second films at an approximately equal etch rate.

18. The method of claim 16, wherein polishing the second film comprises exerting a first pressure on a pad over the first portion and a second pressure on the pad over the second portion, the first and second pressures being substantially equal.

19. The method of claim 16, wherein after polishing the first film to expose the top surfaces the first and second structures have the same height.

20. The method of claim 16, wherein (a) the first and second structures include at least one of copper, aluminum, polysilicon, and a substrate upon which the SOC is formed, (b) the first film includes a nitride, and (c) the second film includes an oxide.
